(19) United States
(12) Patent Application Publication
(10) Pub. No.: US 2002/0021661 A1
(43) Pub. Date: Feb. 21, 2002

(54) Standby redundancy in IMA

(76) Inventors: Marcel DeGrandpre, Kanata (CA); Francois Bourdon, Ottawa (CA)

Correspondence Address: MARKS AND CLERK, P O BOX 957, STATION B, 55 METCALFE STREET, SUITE 1380, OTTAWA, ON, K1P5S7, CA

(21) Appl. No.: 09/885,062

(22) Filed: Jun. 21, 2001

(30) Foreign Application Priority Data
Jun. 26, 2000 (GB) 0015589.5

(51) Int. Cl. G01R 31/08; H04J 3/02

(52) U.S. Cl. 370/219; 370/542

(57) ABSTRACT

An interface apparatus includes first and second devices, each having a series of ports for connection to a common packet transfer bus associated with a controller. The devices operate in parallel and are configured so that when one is in an active mode the other is in a warm stand-by mode ready to become active in the event of failure of the active device. The ports of the device in the active mode communicate normally with the controller to initiate transfer of the packets over the packet transfer bus. The ports of the device in the standby mode are inoperative to communicate with the controller to initiate packet transfer, but otherwise operate normally so as to be ready for immediate activation in the event of failure of the device in the active mode.

### FIELD OF THE INVENTION

This invention relates to ATM networks, and in particular to a method of providing redundancy in an interface providing inverse multiplexing services (IMA).

### BACKGROUND OF THE INVENTION

Inverse multiplexing is a system wherein cells from a high speed link are transmitted over a plurality of lower speeds links, and re-assembled at the far end into a high speed stream. A problem arises when the links become defective. The IMA protocol, through the Link Addition Slow Recovery procedure, partly addresses recovery from errors by adding/deleting links to/from an IMA group, but does not address the problem that arises when the IMA device fails.

While redundancy has been implemented in the prior art, it requires additional external circuitry and additional software for monitoring and performing the switch over. This process requires significant amount of time resulting in slow recovery from a faulty condition.

An object of the invention is to address this problem.

### SUMMARY OF THE INVENTION

According to the present invention there is provided an interface apparatus comprising first and second devices, each having a series of ports for connection to a common packet transfer bus associated with a controller, said devices operating in parallel and being configured so that when one is in an active mode the other is in a warm stand-by mode ready to become active in the event of failure of the active device, said ports of the device in the active mode communicating normally with said controller to initiate transfer of said packets over said packet transfer bus, and said ports of said device in the standby mode being inoperative to communicate with said controller to initiate packet transfer or to transfer packets onto said packet transfer bus, but otherwise operating normally so as to be ready for immediate activation in the event of failure of said active device.

The packet transfer bus is typically an ATM Utopia bus connected to an ATM controller. The devices are typically inverse multiplexer devices connected between a Utopia bus and a TDM bus.

Thus in accordance with the invention, two IMA devices are used in parallel, one in active mode and the other one in “warm” standby mode. The recovery time is improved and the process is simplified by using the warm standby mode.

A unique technical aspect of the present invention is the use of a Utopia interface in a new manner where an IMA device operates from the information available on the Utopia bus but does not respond to it. The IMA device, which is configured in standby, does not respond (drive) the bus as the active IMA device responds to the various conditions. The two IMA devices operate in parallel but the device in standby mode does not drive the TX TDM bus or the Utopia ports. This is done without the need of any additional external glue logic that would otherwise be required.

The standby mode should be implemented on-chip in the Utopia port so that the ATM controller does not need to broadcast the ATM cells on two independent Utopia buses (or waste time to reconfiguring the whole IMA group(s) on another device). If the TX TDM port is not configured in high impedance mode, then an external TDM switch would be required to interface to the TDM device.

Each device can have additional ports operating normally, in which case the standby and active modes really apply to the port rather than the devices, but for convenience one device will be referred to throughout as the standby device and the other as the active device.

The invention therefore further provides an interface apparatus comprising a series of ports for connection to a common packet transfer bus associated with a controller, at least some of said ports being in an active mode and at least some of said ports being in a standby mode, said ports in the active and standby modes operating in parallel and being configured so that when one is in an active mode a corresponding standby port in a warm stand-by mode ready to become active in the event of failure of the active port, said ports in the active mode communicating normally with said controller to initiate transfer of said packets over said packet transfer bus, and said ports in the standby mode being inoperative to communicate with said controller to initiate packet transfer or to transfer packets onto said packet transfer bus, but otherwise operating normally so as to be ready for immediate activation in the event of failure of the corresponding active port.

The invention still further provides a method of providing redundancy in an interface apparatus for transferring data to and from a high speed packet transfer bus associated with a controller, comprising providing a series of ports for connection to the common packet transfer bus, configuring a redundant port operating in standby mode for each active port, configuring said active ports to communicate normally with said controller to initiate transfer of said packets over said packet transfer bus, and configuring said standby ports to be inoperative to communicate with said controller to initiate packet transfer or to transfer packets onto said bus, but otherwise to operate normally so as to be ready for immediate activation in the event of failure of a corresponding active port.

### BRIEF DESCRIPTION OF THE DRAWINGS

The invention will now be described in more detail, by way of example only, with reference to the accompanying drawings, in which:

FIG. 1 is a block diagram of an IMA interface device in accordance with the principles of the invention for transferring data from an ATM controller to multiple physical devices; and

FIG. 2 is a block diagram of an IMA interface device for transferring data from multiple physical devices to an ATM controller.

### DETAILED DESCRIPTION OF THE PREFERRED EMBODIMENTS

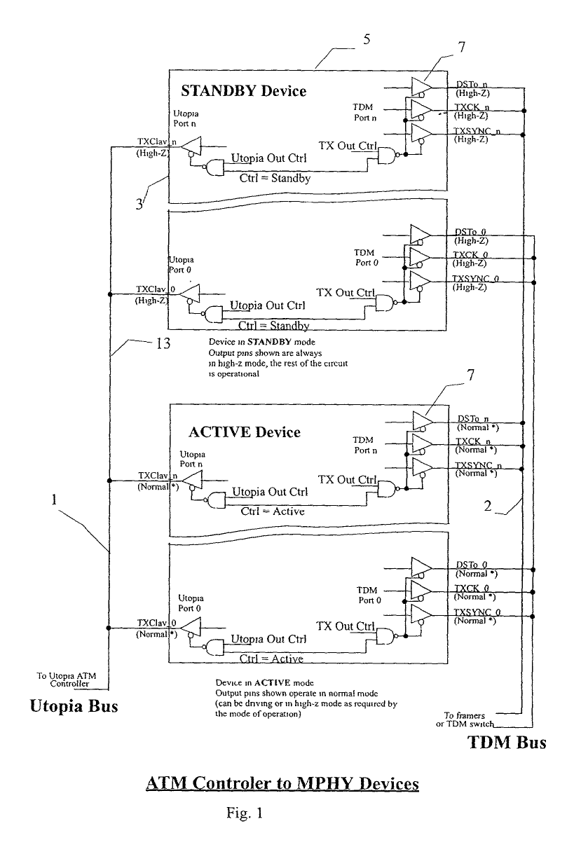

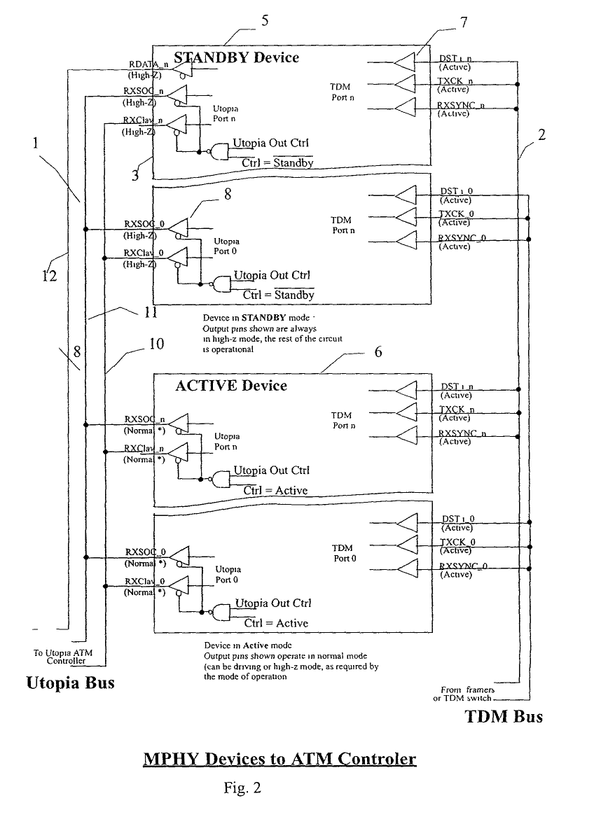

The interface devices shown in FIGS. 1 and 2 are connected between a common Utopia bus 1 carrying high speed ATM cells and a common TDM bus 2 carrying TDM links onto which cells from the Utopia bus are inverse multiplexed in accordance with the IMA standard. FIGS. 1 and 2 shows portions of the device for carrying cells in opposite directions. The common Utopia bus includes signal lines and data lines for byte by byte transfer as is known in the art. FIG. 1 shows single TX signal line 13. FIG. 2 shows signal lines 10, 11, and data lines 12, typically eight bits wide.

The universal test and operations physical interface for ATM (UTOPIA) provides a standard linking ATM with the physical subsystems layer. It defines the link between the physical layer (PHY) and upper layer modules such as the ATM layer and various management entities. The sub-systems may be part of an ATM network interface card (NIC), an ATM switch or an ATM router.

The implementation of the warm standby mode is realized by modifying the operation of the Utopia Interface 3 and the TX TDM interface 4 in such a way that two IMA devices 5, 6 are connected to the common Utopia bus 1 and to the common TDM devices 4 (e.g. framers) but respond differently. One device 6 (or port) is in active mode and the other device 5 (or port) is in standby mode). The internal response of the two devices is identical, but the stand-by device does not send out data onto the TDM bus or Utopia bus.

The two IMA devices 5, 6 are configured identically. They have the same port addresses and same mode of operation. The same software is used to update their operational state at the same time. The active device is operating as normal and responds to the Utopia requests and drives the TX TDM Interface. The IMA device 5 in standby mode operates internally as if it were in normal mode except that it does not drive the TX TDM ports 7 and the Utopia output pins 8.

The TX (transmit) TDM output pins 7 are configured in high impedance mode. The TX Utopia port does not respond to polling and port selection but accepts cells from the Utopia port. The RX (Receive) Utopia port does not respond to polling and port selection but processes cells in the same manner as if it were active. The output pins on the Utopia ports are kept in high impedance mode. The internal cell recovery process of the device 5 in standby mode operates normally but the cell is never transferred to the Utopia controller.

Because the two devices receive and process the same information in parallel, the recovery time, when an error occurs, is reduced to a minimum. There are some ATM cells that are lost due to the time to detect the error condition and the time required to switch the active device to standby mode and the other device from standby to active mode and because the two devices are not synchronized. However, this is a major improvement as compared to re-starting a group using a backup device.

The standby mode is applicable to the entire device (i.e. all the links and groups, in non-IMA mode and in IMA mode) and is programmed through a register under the control of the software (user).

Part of the IMA protocol is implemented in software and it is the responsibility of the software to operate the two devices in parallel. The main task is to ensure that the configuration and operational parameters are the same in both devices.

The configuration parameters are determined during the initialization phase and when a link is added or deleted from an operational IMA group. There are no time critical operations when an IMA group is configured or dismantled (shut off).

The additional operational task is mainly to ensure that the content of the TX ICP cells is identical on the two devices. During normal operation, only the active device is accessed to retrieve the operating parameters. All incoming information from the device in standby mode can be ignored and the IRQ masked. The additional software overhead during normal operation is reduced to writing the content of the TX ICP cell to both devices.

Upon detection of errors, when required, the control software changes the mode of operation of the two devices and resumes its operation using the device that was in standby mode.

A software routine can be used to configure a device in standby mode to reflect the state of an active device in the case where the standby device is configured after the active device was configured. (In the case where a faulty device is replaced by a good standby device).

The active/standby modes can be implemented on a per port basis or per device basis, in a case of a multi-port device. In the case of a multi-port device only one device should be operated in standby mode and another device in active mode. This simplifies the management of the IMA groups.

Consider now the situation shown in FIG. 1, where ATM cells are transferred from the Utopia bus 1 to the TDM bus 2. The Utopia ATM controller (not shown) interrogates via TX signal line 13 the ports 8 on the IMA devices to see if they are ready to accept data. The ports 8 of the active device are kept in the normal mode and respond according to whether or not they are ready to accept data. The ports 8 of the standby device are maintained in the high state so that they never indicate they are ready to accept data. When the ports 8 of the active device indicate that they are ready to accept data, the Utopia controller transfers cells over the data bus (not shown in FIG. 1). These cells are received by both devices, i.e. the devices in both the active and standby modes, and the received cells are internally process in an identical manner in both IMA devices, so that the state of the two IMA devices is always the same. The output ports on the standby device are also disabled so that the standby device does not output cells onto the TDM links.

In the reverse direction shown in FIG. 2, the cells are continually received by ports 7 of both active and standby devices from the TDM bus 2 in parallel and processed internally in exactly the same way. On the input side there is no difference between the two active and standby devices. On the output side, the ports 8 communicate with Utopia ATM controller over signal lines 10, 11. The output pins of the ports 8 of the standby device are kept in a high impedance state. For the active device the pins operate normally to communicate with the Utopia ATM controller in order to transfer cells over the Utopia bus 1. The internal operations of the ports of the same, but in the standby device the cells are not actually transferred to the Utopia bus to avoid contention.

It is possible to implement the standby mode on a per port basis where only some of the Utopia and TDM ports are on a standby mode inside a device and other ports are in standby mode in another device.

Similar standby mode may be used in any other device that is connected to a Utopia bus.

1. An interface apparatus comprising first and second devices, each having a series of ports for connection to a common packet transfer bus associated with a controller, said devices operating in parallel and being configured so that when one is in an active mode the other is in a warm stand-by mode ready to become active in the event of failure of the active device, said ports of the device in the active mode communicating normally with said controller to initiate transfer of said packets over said packet transfer bus, and said ports of said device in the standby mode being inoperative to communicate with said controller to initiate packet transfer or to transfer packets onto said packet transfer bus, but otherwise operating normally so as to be ready for immediate activation in the event of failure of said active device.

2. An interface apparatus as claimed in claim 1, wherein said ports of said device in the standby mode are operative to receive from the common packet transfer bus packets whose transfer is initiated in response to a communication between the controller and the ports of the active device.

3. An interface apparatus as claimed in claim 2, wherein said common packet transfer bus is a Utopia bus transferring ATM cells.

4. An interface apparatus as claimed in claim 3, wherein devices also include a second set of ports connected to a common time division multiplexed (TDM) bus.

5. An interface apparatus as claimed in claim 4, wherein said second set of ports of both the standby and active devices are configured in the receive direction to be in the active state so that data are received in parallel by both said devices from the TDM bus.

6. An interface apparatus as claimed in claim 5, wherein output pins of said second set of ports of the standby device are configured in the transmit direction to be in the inactive state so that data from said output pins are not transmitted onto the TDM bus.

7. An interface apparatus as claimed in claim 6, wherein said devices are inverse multiplexers transferring cells between said Utopia bus and a plurality of TDM links forming said TDM bus.

8. An interface apparatus as claimed in claim 7, wherein at least one of said standby and active devices have additional ports operating normally.

9. An interface apparatus comprising a series of ports for connection to a common packet transfer bus associated with a controller, at least some of said ports being in an active mode and at least some of said ports being in a standby mode, said ports in the active and standby modes operating in parallel and being configured so that when one is in an active mode a corresponding standby port in a warm stand-by mode ready to become active in the event of failure of the active port, said ports in the active mode communicating normally with said controller to initiate transfer of said packets over said packet transfer bus, and said ports in the standby mode being inoperative to communicate with said controller to initiate packet transfer or to transfer packets onto said packet transfer bus, but otherwise operating normally so as to be ready for immediate activation in the event of failure of the corresponding active port.

10. An interface apparatus as claimed in claim 9, wherein said ports in the standby mode are operative to receive from the common packet transfer bus packets whose transfer is initiated in response to a communication between the controller and the ports in the active mode.

11. An interface apparatus as claimed in claim 10, wherein said common packet transfer bus is a Utopia bus transferring ATM cells.

12. An interface apparatus as claimed in claim 11, wherein devices also include a second set of ports connected to a common time division multiplexed (TDM) bus.

13. A method of providing redundancy in an interface apparatus for transferring data to and from a high speed packet transfer bus associated with a controller, comprising providing a series of ports for connection to the common packet transfer bus, configuring a redundant port operating in standby mode for each active port, configuring said active ports to communicate normally with said controller to initiate transfer of said packets over said packet transfer bus, and configuring said standby ports to be inoperative to communicate with said controller to initiate packet transfer or to transfer packets onto said bus, but otherwise to operate normally so as to be ready for immediate activation in the event of failure of a corresponding active port.

14. A method as claimed in claim 13, wherein said standby ports receive from the common packet transfer bus packets whose transfer is initiated in response to a communication between the controller and the active ports.

15. A method as claimed in claim 14, wherein said common packet transfer bus is a Utopia bus transferring ATM cells.

16. A method as claimed in claim 15, wherein a second set of ports transfer data to and from a common time division multiplexed (TDM) bus.

17. A method as claimed in claim 17, wherein the second set of ports of both the standby and active devices in the receive direction are in the active state so that data are received in parallel by both said devices from the TDM bus.

18. A method as claimed in claim 17, wherein output pins of said second set of standby ports in the transmit direction are in the inactive state so that data from output pins thereof are not transmitted onto the TDM bus.

19. A method as claimed in claim 17, wherein the standby ports are located on a first device in the standby mode and the active ports are located on a second device in the active mode.
